(19) United States
(12) Patent Application Publication
(10) Pub. No.: US 2005/0007016 A1
(43) Pub. Date: Jan. 13, 2005

(54) Organic electroluminescent element

(76) Inventors: Toshitaka Mori, Tokyo (JP); Yasuyuki Ohyagi, Tokyo (JP)

Correspondence Address: SEYFARTH SHAW, 55 EAST MONROE STREET, SUITE 4200, CHICAGO, IL, 60603-5803, US

(21) Appl. No.: 10/889,677

(22) Filed: Jul. 13, 2004

(30) Foreign Application Priority Data
Jul. 10, 2003 (JP) 2003-195343

(51) Int. Cl. H05B 33/12; H05B 33/26

(52) U.S. Cl. 313/512; 313/504; 313/506; 313/113; 428/690; 428/917; 428/332

(57) ABSTRACT

In an organic electro luminescent element, an organic layer and an electron injecting layer are inhibited from being oxidized, and alleviated in damage caused by the sputtering during manufacture. Thereby, an organic electroluminescent element that takes out light with high efficiency from a cathode of a top side and is capable of displaying a high quality image can be provided. An organic electroluminescent element according to the present invention includes at least a base material, an anode, an organic electroluminescent layer, a conductive protection layer having the optical transparency and a cathode having the optical transparency all of which are formed sequentially on the base material, wherein the conductive protection layer is made of a metal or a metal and a metal oxide thereof.

### BACKGROUND OF THE INVENTION

1. Field of the Invention

The present invention relates to an organic electroluminescent element, in particular, an organic electroluminescent element in which light can be taken out from a cathode of a top side.

2. Description of the Related Art

An organic electroluminescent element (hereinafter, referred to as “organic electroluminescent element” or “organic EL element”) is advantageous in being high in the visibility owing to self-emission, excellent in the impact resistance owing to being all solid display different from a liquid crystal display device, high in the response speed, not so much affected by a temperature variation and wide in the angle of visibility. Accordingly, in recent years, it is gaining attention in applications as a light-emitting element in an image display device.

As a configuration of an organic EL element, with a lamination structure of anode/light-emitting layer/cathode as a basis, a configuration in which on a base material such as a glass substrate a transparent anode is formed is usually adopted. In this case, emitted light is taken out from a base material side (anode side),

On the other hand, recently, in organic EL elements, experiments of making a cathode transparent to take out emitted light from a cathode side (top emission) are forwarded. When the top emission is realized, firstly, in the case of both the cathode and anode being made transparent, a light-emitting element that is transparent as a whole can be realized. Since as a background color of such a transparent light-emitting element, an arbitrary color can be adopted, a display that is colorful other than during emission can be realized, resulting in an improvement in the decoration property. Furthermore, when the top emission is realized, in the case of using a color filter layer or a color conversion layer, on a light-emitting layer, each of the above layers can be disposed. Still furthermore, since emitted light is not blocked by a TFT (thin film transistor) of an active drive display device, a display device high in the aperture ratio can be realized.

As an example of an organic EL element in which the top emission is realized by making a cathode transparent, a configuration in which an organic layer including an organic EL layer is interposed between an anode and a cathode, the cathode is constituted of an electron injecting metal layer and an amorphous transparent conductive layer, and the electron injecting metal layer is in contact with the organic layer is disclosed (Japanese Patent Application Laid-Open (JP-A) No. 10-162959).

Furthermore, a configuration in which in order to inhibit a cathode material from diffusing to an organic layer that is an organic EL layer, a Ca diffusion barrier layer is disposed between a cathode and an organic layer to inhibit the short circuit and deterioration of the characteristics of the organic EL element from occurring is disclosed (JP-A No. 10-144957).

Still furthermore, as an example of double-sided emission, a configuration in which in order to make a transparent cathode low in the electric resistance, a conductive layer made of Ag, Mg or TiN is interposed between a transparent cathode and an light-emitting layer is disclosed (JP-A No. 10-125469).

Furthermore, a configuration in which in order to inhibit oxygen and indium from invading or diffusing into an organic layer, TiN is used in an anode is disclosed (JP-A Nos. 2002-15859 and 2002-15860).

However, in a conventional organic EL element that has realized the top emission, it cannot be avoided that owing to oxygen introduction in the process of forming a transparent cathode or owing to release of oxygen from a target, an electron injecting layer is oxidized. Accordingly, there are problems in that the characteristics of the organic layer and the electron injecting layer are deteriorated, and thereby high quality image display cannot be obtained. Furthermore, in general, a transparent electrode such as ITO (indium-tin oxide) is deposited by a sputtering method. However, in the case of a transparent cathode being formed by use of the sputtering method, there are problems in that the organic layer including an organic EL layer and the electron injecting layer are exposed to impact of sputtered particles and Ar⁺ during the sputtering, and thereby the emission characteristics are deteriorated.

### SUMMARY OF THE INVENTION

The present invention is carried out in view of such situations and intends to provide an organic electroluminescent element in which an organic layer and an electron injecting layer are inhibited from oxidizing and alleviated in damage of the organic layer and the electron injecting layer caused by the sputtering during formation of a transparent cathode, and thereby light is efficiently taken out from a cathode of a top side and high quality image display is realized.

In order to achieve such an object, the present invention provides an organic electroluminescent element includes at least a base material and, sequentially formed from the base material side, an anode, an organic electroluminescent layer, a conductive protection layer having the optical transparency and a cathode having the optical transparency, the conductive protection layer being made of a metal or a metal and a metal oxide thereof.

According to the invention, since a conductive protection layer is formed into an optically transparent metal thin film that is formed according to a vacuum deposition method in which oxygen is not introduced in a deposition process, or an optically transparent thin film made of a metal and a meta oxide thereof, the organic layer and the electron injecting layer are inhibited from being oxidized by oxygen not only in the deposition of the conductive protection layer but also in the deposition of the cathode having the optical transparency and alleviated in the impact due to particles sputtered during the formation of the cathode. As a result, an organic electroluminescent element less in the leakage current and excellent in the emission characteristics and the durability can be obtained. Further, by disposing a conductive protection layer, an organic electroluminescent element less in the deterioration of the characteristics, high in the reliability and capable of taking out light with high efficiency from a cathode of a top side and displaying high quality image can be obtained.

In the present invention, it is preferable that a metal used in the conductive protection layer, with extinction coefficient of the metal as k, a thickness as d and a wavelength as λ, is constituted so as to be in the range of 0≦k×d<0.11λ.

Also in the present invention, it is preferable that the metal oxide contained in the conductive protection layer is constituted so that a band gap of the metal oxide is 2.9 eV or more.

Also in the present invention, it is preferable that the conductive protection layer is constituted of at least one kind of metals selected from a group consisting of zinc, tin, lead, indium, gallium, magnesium and aluminum, or a combination of at least one kind of the metals and at least one kind of the metal oxides thereof.

Also in the present invention, it is preferable that the cathode is constituted so as to include a conductive oxide, have a thickness in the range of 10 to 500 nm and be 50% or more in the light transmittance in a visible region of 380 to 780 nm.

Also in the present invention, it is preferable that the sheet resistance of the cathode containing the conductive protection layer is constituted so as to be 20 Ω/□ or less.

Also in the present invention, it is preferable that the anode is constituted so as to include any one of one kind or combinations of two or more kinds of a metal group having a work function of 4.5 eV or more, or alloys made of two or more kinds of metals among the metal group having a work function of 4.5 eV or more, or one kind or two or more kinds of conductive inorganic oxides.

Also in the present invention, the anode may have a structure in which a layer made of the metal or alloy and a layer made of the conductive inorganic oxide are laminated in this order from the base material side and is constituted so as to have the light reflectiveness. Also, the anode may be made of the metal or alloy and is constituted so as to have the light reflectiveness.

According to the invention as mentioned above, the conductive protection layer is interposed between the organic layer, which contains the electron injecting layer and the organic electroluminescent layer, and the cathode works so as to inhibit the electron injecting layer of the organic electroluminescent element from oxidizing owing to oxygen during the oxygen introduction in the formation of the cathode or released from the target.

According to the present invention, a structure in which a conductive protection layer is interposed between an organic layer, which contains an electron injecting layer and an organic electroluminescent layer, and a cathode is taken, and the conductive protection layer is made of a thin film made of at least one kind of metal or a metal and a metal oxide thereof that is formed according to a vacuum deposition method in which during deposition process oxygen is not introduced. Accordingly, the organic layer and the electron injecting layer are inhibited from being oxidized not only in the deposition of the conductive protection layer but also in the deposition of the cathode having the optical transparency. As a result, an organic electroluminescent element that is less in the characteristics deterioration, high in the reliability and capable of taking out light with high efficiency from a cathode of a top side to display a high quality image can be obtained.

### BRIEF DESCRIPTION OF THE DRAWINGS

FIG. 1 is a conceptual diagram of a fundamental configuration showing an embodiment of an organic electroluminescent (EL) element according to the invention.

### DESCRIPTION OF THE PREFERRED EMBODIMENT

Hereinafter, an organic electroluminescent element of present invention will be explained in detail.

The organic electroluminescent element of present invention includes at least a base material, an anode, an organic electroluminescent layer, a conductive protection layer having the optical transparency and a cathode having the optical transparency that are formed sequentially on the base material, the conductive protection layer being made of a metal or a metal and a metal oxide thereof.

Firstly, the organic electroluminescent element of present invention will be explained with reference to the drawing as follows.

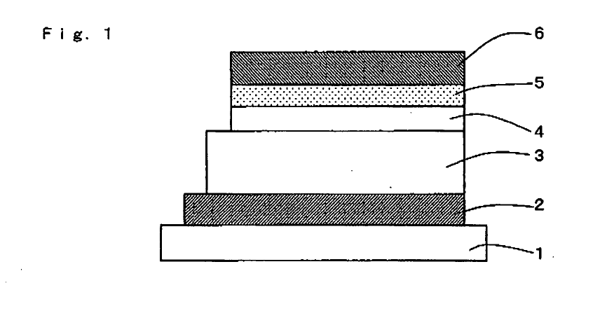

FIG. 1 is a conceptual diagram of a fundamental configuration showing an embodiment of an organic EL element according to the invention. In FIG. 1, an organic EL element includes a base material 1, with sequentially formed on the base material 1, a first electrode (anode) 2, an organic layer 3 including an organic electroluminescent layer, an electron injecting layer 4, a conductive protection layer 5 having the optical transparency and a second electrode (cathode) 6 having the optical transparency.

Hereinafter, configurations of the organic electroluminescent element will be explained as follows.

1. Base Material

Firstly, a base material 1 used in the present invention will be explained as follows. As a material capable of being used as the base material 1, as far as it has the self-supporting properties, there is no particular restriction. Furthermore, in the case of the base material 1 being disposed below the anode 2 of a metal layer, there is no particular necessity of having the transparency.

As the base material 1, for instance, quartz or glass, silicon wafer, glass on which a TFT (thin film transistor) is formed, polymer materials such as polycarbonate (PC), polyethylene terephthalate (PET), polybutylene terephthalate (PBT), polyphenylene sulfide (PPS), polyimide (PI), polyaiude imide (PAI), polyether sulfone (PES), polyether imide (PEI) and polyether ether ketone (PEEK) can be cited.

Among these materials, quartz, glass, silicon wafer, or super-engineering plastics such as polyimide (PI), polyamide-imide (PAI) polyether sulfone (PES), polyether imide (PEI) and polyether ether ketone (PEEK) is preferable. These materials have the heat resistance of 200° C. or more and allow making a temperature of the base material high in a manufacturing process of TFTs of an active matrix driving display device. However, in the case of using the polymer materials, in order to inhibit the organic layer 3 from deteriorating owing to gas generated from the base material 1, it is necessary to form a gas barrier layer made of silicon oxide or silicon nitride at least on a formation surface facing the anode 2 of the base material 1. A thickness of the base material 1 can be set in consideration of a material and application situations of an image display device and can be set, for instance, in the range of substantially 0.005 to 5 mm.

2. First Electrode

As a first electrode (anode) 2 of the present invention that constitutes an organic EL element, as far as it is formed of a conductive material, there is no particular restriction, and, for instance, metals such as Au, Ta, W, Pt, Ni, Pd, Cr, Cu and Mo, or the metal oxides thereof, combinations of Al alloys, Ni alloys and Cr alloys, or laminated bodies of these metallic materials can be cited. Furthermore, conductive inorganic oxides such as In—Sn—O, In—Zn—O, Zn—O, Zn—O—Al and Zn—Sn—O; conductive polymers such as metal-doped polythiophene; and α-Si and α-SiC can be cited.

The anode 2 plays a role of supplying holes to the organic layer 3. Accordingly, it is preferable to use a conductive material which work function is large. In particular, the anode 2 is preferably comprised of at least one kind of metals having the work function of 4.5 eV or more, or at least one kind of materials contained in a group of alloys of these metals or conductive inorganic oxides. Since the anode metal is easily oxidized when the work function is less than 4.5 eV, the work function is preferably 4.5 eV or more.

A thickness of such anode 2, though depending on the material, is preferably in the range of 40 to 500 nm. When the thickness of the anode 2 is less than 40 nm, in some cases, the electric resistance becomes higher; on the other hand, when the thickness of the anode 2 exceeds 500 nm, owing to a step present at an end portion of a patterned anode 2, in a upper layer (organic layer 3, electron injecting layer 4, conductive protection layer 5 and cathode 6) a cut or disconnection may be caused, or the short-circuit between anode 2 and cathode 6 may occur.

As a deposition method of the anode 2, a sputtering method, a vacuum heating vapor deposition method, an EB deposition method and an ion plating method can be cited. A value of the resistivity is preferably 1×10⁻² Ω·cm or less, and more preferably 5×10⁻⁴ Ω·cm or less. In order to suppress the circuit loss of electric power owing to electrode resistance, the resistance is preferable to be lower.

3. Organic Layer

An organic layer 3 of the present invention that constitutes an organic EL element usually includes an organic electroluminescent layer, a hole injecting and transporting layer, a hole transporting layer, an electron transporting layer and so on. The organic layer 3 in the invention like this necessarily contains at least one layer of an organic electroluminescent layer. Furthermore, the organic electroluminescent layer and the abovementioned layers can be combined to form an organic layer 3 made of a plurality of layers.

Furthermore, as a method of forming the organic layer 3 on the anode 2 used in the present invention, from the necessity of patterning thereof, as far as it enables to form a high precisely pattern, there is no particular restriction. For instance, methods of forming an organic layer 3 in pattern by use of a vapor deposition method, a printing method, or an ink jet method, methods of coating a material that forms an organic layer 3 as a coating solution such as a spin coating method, a casting method, a dipping method, a bar coat method, a blade coat method, a roll coat method, a gravure coat method, a flexo printing method, a spray coat method and a self-organizing method (layer-by-layer self-assembled method, self-assembled monolayer method) can be cited. Among these, in particular, the organic layer 3 can be preferably formed by use of a vapor deposition method, a spin coat method or an ink jet method.

Like the present invention, when a conductive material made of a metal as will hereinafter described is used as the conductive protection layer 5, owing to a large work function (4.0 eV or more), an energy barrier at an interface between the conductive protection layer 5 and an organic electroluminescent layer becomes higher; accordingly, under a low voltage it becomes difficult to inject electrons directly from the conductive protection layer 5 to the organic electroluminescent layer. Accordingly, it is preferable to form a structure in which an electron injecting layer or an electron injecting and transporting layer is disposed on the conductive protection layer 5 side. The electron injecting layer and the electron injecting and transporting layer, in order to take out light efficiently from the cathode 6 of a top side, are necessary to have sufficient optical transparency. The hole injecting and transporting layer and the electron injecting and transporting layer, respectively, may be formed in a lamination structure in which an injection function layer and a transporting layer are separately disposed.

(1)Organic Electroluminescent Layer

An organic electroluminescent layer used in the present invention that constitutes the organic layer 3 will be explained as follows.

An organic electroluminescent layer that constitutes the organic layer 3 concurrently has functions below.
Injection function: a function of capable of injecting, under an electric field, holes from the anode 2 or the hole injecting layer, and electrons from the cathode 6 or the electron injecting layer 4
Transporting function; a function of transporting injected charges (electrons and holes) under a force of an electric field
Emission function: a function of providing a place of recombination of electrons and holes, and of leading this to emission

As materials of an organic electroluminescent layer having such functions, common materials so far known as light-emitting layer materials of an organic EL element can be used without particular restriction. For instance, metal complex dyes such as tris(8-quinolinorate) aluminum complex (Alq3) and high molecular weight materials such as polydialkylfluorene derivatives can be preferably used.

A thickness of the organic electroluminescent layer, without particular restriction, can be made for instance in the range of substantially 10 to 200 nm.

In the organic of the present invention EL element, the organic electroluminescent layer is an indispensable layer, and, when a full color and a multi-color display are manufactured, the layer is necessary to be patterned. As materials that form such a light-emitting layer, normally, dye base, metal complex base or polymer base luminescent materials can be cited. Hereinafter, as materials that form such an organic electroluminescent Layer, luminescent materials will be explained.

(i) Dye Base Materials

As the dye base materials, cyclopendamine derivatives, tetraphenylbutadiene derivatives, triphenylamine derivatives, oxadiazole derivatives, pyrazoloquinoline derivatives, distyrylbenzene derivatives, distyrylarylene derivatives, silole derivatives, thiophene cyclic compounds, pyridine cyclic compounds, perynone derivatives, perylene derivatives, oligothiophene derivatives, trifumanylamine derivatives, oxadiazole dimer, pyrazoline dimer and others can be listed.

(ii) Metal Complex Base Materials

As metal complex base materials, metal complexes having a structure that has, as central metal, Al, Zn, Be or a rare earth element such as Tb, Eu and Dy and, as a ligand, oxadiazole, thiadiazole, phenylpyridine, phenylbenzoimidazole and quinoline structure such as aluminum quinolinol complex, benzoquinolinol beryllium complex, benzoxazol zinc complex, benzothiazole zinc complex, azomethyl zinc complex, porphyrin zinc complex, europium complex, iridium metal complex, and platinum ,metal complex can be cited.

(iii) Polymer Base Materials

As the polymer base materials, polyparaphenylene vinylene derivatives, polythiophene derivatives, polyparaphenylene derivatives, polysilane derivatives, polyacethylene derivatives, polyfluorene derivatives, polyvinylcarbazole derivatives, and ones obtained by polymerizing the above-mentioned dyes and metal complex base luminescent materials can be cited.

(2) Hole Injecting and Transporting Layer, Hole Transporting Layer

As the hole injecting and transporting layer, as far as the layer can transport holes injected from the anode 2 into the organic electroluminescent layer, there is no particular restriction thereon. For instance, it may be formed of any one of a hole injecting layer that has a function of stably injecting holes injected from the anode 2 into the organic electroluminescent layer, a hole transporting layer that has a function of transporting holes injected from the anode 2 into the organic electroluminescent layer, or a combination thereof, or a layer that has both functions.

Furthermore, as a thickness of the hole injecting and transporting layer, as far as a function thereof can be fully exhibited, there is no particular restriction. However, it is in the range of 10 to 300 nm and preferably in the range of 30 to 100 nm.

As a material of such a hole injecting and transporting layer, as far as it allows stably transporting holes injected from the anode 2 to the organic electroluminescent layer, there is no particular restriction. Specifically, N-(1-naphtyl)-N-phenylbenzine (α-NPD) 4,4,4-tris (3-methylphenylphenylamino) triphenylamine (MTDATA), and polymers such as poly3,4 ethylenedioxythiophene (PEDOT), polyvinyl carbazole (PVCz), polyaniline derivatives, and polyphenylene vinylene derivatives can be cited. As a hole transport compound, any one of known compounds that have been so far used in the hole injecting and transporting layer of the organic EL element can be selected and used.

(3)Electron Injecting Layer

Furthermore, as a material of the electron injecting layer 4, oxides and fluorides of alkali metals and alkali earth metals (for instance, LiF, NaF, LiO₂, MgF₂, CaF₂, and BaF₂) and so on can be cited. Among these, fluorides of alkali earth metals (MgF₂, CaF₂ and BaF₂) can be more preferably used in view of capability of improving the stability and life of the organic layer 3. This is because since fluorides of alkali earth metals are low in the reactivity with water in comparison with that of compounds of alkali metals and oxides of alkali earth metals, during deposition, or after the deposition, the fluorides of alkali earth metals less absorb water. Furthermore, this is because the fluorides of alkali earth metals are higher in the melting point in comparison with that of compounds of alkali metals, that is, excellent in the heat resistance.

A thickness of the electron injecting layer 4, since the oxides and fluorides of alkali metals and alkali earth metals are insulative, is preferably in the range of substantially 0.2 to 10 nm.

Furthermore, when, other than the electron injecting layer 4, a metal having a work function of 4.0 eV or less is disposed as an electron injecting layer 4, electrons can be more easily injected. Specific examples include Ba, Ca, Li, Cs, Mg and so on. In the case of an electron injecting layer 4 constituted of such metals being formed, a film thickness thereof is in the range of 0.2 to 50 nm and more preferably in the range of 0.2 to 20 nm. This is because from the necessity of taking out light from a transparent electrode of a top side, the electron injecting layer 4 is also required to be transparent.

Still furthermore, as the electron injecting and transporting layer, a metal-doped layer where an alkali metal or alkali earth metal is doped in an electron transporting organic material can be formed. As the electron transporting organic materials, for instance, bathocuproin (BCP), bathophenanthroline (Bphen) and so on can be cited, and as the doping metals, Li, Cs, Ba, Sr and so on can be cited. A molar ratio of the electron transporting organic material and the metal in the metal-doped layer is in the range of 1:1 to 1:3 and preferably in the range of substantially 1:1 to 1:2. A thickness of the electron injecting and transporting layer made of such metal-doped layer, since the electron mobility is large and the optical transparency is higher than that of the metal, is in the range of 5 to 500 nm, and preferably in the range of substantially 10 to 100 nm.

(4)Electron Transporting Layer

As a material that constitutes an organic electron transporting layer, as far as it can transport electrons injected from the electron injecting layer 4 into a light-emitting layer, there is no particular restriction. Specifically, as the electron transporting organic material, Alq (aluminum quinolinol complex), BCP (bathocuproin) or Bphen (bathophenanthroline) can be cited.

(5)Conductive Protection Layer

The conductive protection layer 5 has both of a function of transporting electrons and a function of protecting (protection from the deposition processes such as sputtering, EB, ion plating and so on) the electron injecting layer 4 and the organic layer 3 in the process of depositing a transparent electrode for forming the cathode 6. When a transparent electrode is formed on the electron injecting layer 4 by the sputtering method, since the electron injecting layer 4 and the organic layer 3 are exposed to an impact of Are having high energy of several hundred volts, a structure of the organic electroluminescent layer is changed, and in the electron injection at an interface between the organic electroluminescent layer and the transparent electrode, radiationless quenching is caused to result in deteriorating the luminescent characteristics. Furthermore, in the case of the electron injecting layer 4 being formed of an alkali metal or an alkali earth metal, the electron injecting layer 4 is likely to be oxidized, and, owing to oxygen introduction in the formation process of an electrode such as ITO and IZO in the sputtering or oxygen release from a target, a metal that is used in the electron injecting layer 4 is oxidized, and thereby, in some cases, the electron injecting function may be lost. When the conductive protection layer 5 is disposed between the electron injecting layer 4 and a second electrode 6 with an intention of protecting the electron injecting layer 4 and the organic layer 3, sputter damage of the electron injecting layer 4 and the organic layer 3 can be alleviated, and thereby the emission efficiency and the durability of the organic EL element can be improved.

The conductive protection layer 5 is a thin film made of at least one kind of optically transparent metals that is formed according to a vacuum deposition method in which oxygen is not introduced during the deposition process, and may be a multi-layered film made of two or more kinds of metals or a film in which two or more kinds of metals are mixed. Furthermore, the conductive protection layer 5 may be a thin film made of an optically transparent metal and a metal oxide thereof. In the case of a thin film made of a metal oxide being contained, a thin film of the metal oxide is preferably disposed on a side of cathode 6. Still furthermore, in the conductive protection layer 5, a plurality of metals that constitutes the metal oxide may be alloyed.

As the metals, in order to make the light transmittance in the visible region of the metal film 50% or more, when the extinction coefficient of a metal is expressed with k, a film thickness with d, and a wavelength with λ, a range of 0≦k×d<0.11λ is preferable. Also, the value of the extinction coefficient as k is determined by measuring the material formed on silicon wafer with ellipsometer. Further, the band gap of the metal oxide contained in the conductive protection layer 5 is preferable to be 2.9 eV or more. These metals and metal oxides thereof are not restricted as far as it satisfies above-mentioned conditions, for instance, metals such as zinc, lead, tin, indium, gallium, magnesium, aluminum, gold and silver, and the metal oxides thereof can be cited. Furthermore, after a conductive protection layer made of only a metal is formed, when an oxidation process is applied to the protective layer, the band gap of the conductive protection layer 5 has to become 2.9 eV or more.

It is because when the band gap is less than 2.9 eV, the metal oxide is colored and lowers the transmittance in the visible region. As the aforementioned oxides of metals, for instance, oxides such as Sn—O, In—O, In—Sn—O, In—Zn—O, Zn—O, Ga—O, Zn—Sn—O and Ga—In—O can be cited.

A thickness of the conductive protection layer 5 having the characteristics is preferably selected to satisfy the relational expression of 0≦k×d<0.11λ. In general, in the case of a thin film being made of a metal, in the range of 5 to 30 nm and preferably in the range of substantially 5 to 20 nm, and in the case of a thin film being made of a layer containing metal oxide, in the range of 5 to 300 no and preferably in the range of substantially 10 to 100 nm.

As the vacuum deposition method for forming the conductive protection layer 5, a resistance heating deposition method, an ion beam deposition method, a sputtering method, an ion plating method and so on can be cited.

(6)Second Electrode

The second electrode (cathode) 6, as long as it is formed of a transparent and conductive material, is not particularly restricted. As the transparent and conductive materials, conductive oxides such as In—Sn—O, In—Zn—O, Zn—O, Zn—O—Al and Zn—Sn—O can be cited.

A thickness of the cathode 6 like this is preferably in the range of 10 to 500 nm, and the transmittance in the visible region of 380 to 780 nm is preferably 50% or more. When the thickness of the cathode 6 is less than 10 nm, the conductivity becomes insufficient, and when the thickness of the cathode 6 exceeds 500 nm, the optical transparency becomes insufficient and furthermore when during the manufacturing process or after the manufacture of an organic EL element it is deformed, defects such as crack and so on are unfavorably likely to be generated to the cathode 6.

Furthermore, the sheet resistance of the cathode 6 including the conductive protection layer 5 is preferably 20 Ω/□ or less.

The cathode 6 can be formed by vacuum deposition methods such as a sputtering method, anion plating method and an electron beam method. In the formation of the cathode 6 like this, the conductive protection layer 5 inhibits the electron injecting layer 4 from being oxidized owing to oxygen introduction or oxygen released from the target, and thereby the electron injection characteristics to the organic layer 3 can be inhibited from deteriorating.

(7)Others

In the present invention, on the cathode 6, color filter layers and/or color conversion phosphor layers may be disposed to correct light of the respective colors and thereby heighten the color purity.

As the color filter layers, for instance, a blue-colored layer, a red-colored layer and a green-colored layer, respectively, may be formed with resin compositions prepared by dispersing one kind or a plurality of kinds of pigments such as azo, phthalocyanine and anthraquinone base pigments in a photosensitive resin.

Furthermore, the color conversion phosphor layers can be formed as follows for instance. That is, a coating solution in which a desired fluorescent dye and a resin are dispersed or solubilized is coated according to a method such as a spin coat, roll coat or cast coat to form a film, the film is patterned according to a photolithography method, and thus the respective layers of a red conversion phosphor layer, a green conversion phosphor layer andablue conversion phosphor layer can be formed.

It is to be noted that the present invention is not limited to the above-described embodiment. The above-described embodiment is only illustrative. The changes or modifications that have substantially the same constructions as those which are made using the technical ideas described in the claimed scope of the present invention and exhibit the same functions and effects are included in the technical scope of the present invention whatever kinds they may be of.

### EXAMPLES

The present invention will be detailed with reference to examples as follows.

### Example 1

As a base material, a 40 mm×40 mm-transparent glass substrate (non-alkali glass NA35, manufactured by NH Techno glass Corp.) having a thickness of 0.7 mm was prepared, after the transparent glass substrate was washed according to a standard process, a thin film of Ag (100 nm thick) was deposited by a magnetron sputtering method. When the thin film of Ag was formed, Ar was used as a sputtering gas, a pressure was set at 0.15 Pa, and a DC output was set at 200 W. Next, on the Ag thin film, in order to give a role of accelerating hole injection, a thin film (30 nm thick) of indium tin oxide (ITO) was formed by use of a magnetron sputtering method. In the formation of the ITO thin film formation, a gas mixture of Ar and O₂ (volume ratio Ar: O₂=100: 1) was used as a sputtering gas, a pressure was set at 0.1 Pa and a DC output was set at 150 W.

Subsequently, on the anode, a photosensitive resist (trade name OFPR-800, manufactured by Tokyo Ohka Kogyo Co., Ltd.) was coated, followed by mask exposure, development (NMD3 manufactured by Tokyo ohka Kogyo Co., Ltd. was used) and etching, and thereby the anode was formed in pattern.

Next, the transparent glass substrate with the anode was washed and subjected to UV ozone treatment, thereafter in air polyethylene dioxythiophene-polystyrene sulfonate (PEDOT-PSS) expressed by the following structural formula (1) was coated by a spin coating method so as to cover the anode on the transparent glass substrate, followed by drying, and thereby a hole injecting and transporting layer (80 nm thick) was formed.

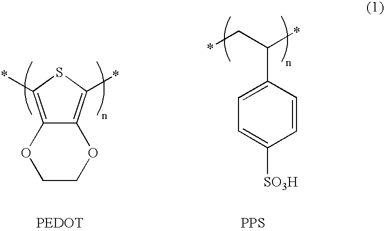

(In the above, n is a number in the range of 10,000 to 500,000.)

Next, in a globe box in a state of low oxygen (oxygen concentration is 1 ppm or less) and low humidity (water vapor concentration is 1 ppm or less), on the hole injecting and transporting layer, poly(dioctyldivinylenefluorene-co-anthracene)(PF) expressed by the following structural formula (2) was coated according to a spin coating method, dried and thereby a light-emitting layer (80 nm thick) was formed.

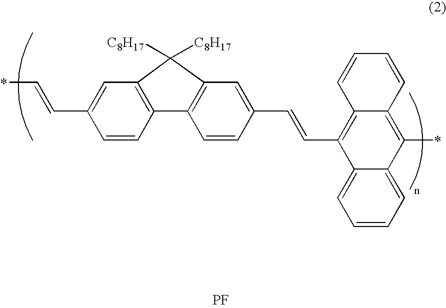

(In the above, n is a number in the range of 100,000 to 1,000,000.)

Furthermore, on the light-emitting layer, Ca was vapor deposited with a thickness of 5 nm, and thereby an electron injecting layer was formed. Deposition conditions were as follows. That is, a vacuum pressure was set at 5×10⁻⁵ Pa and a film deposition rate was set at 1 Å/sec.

On the electron injecting layer, Sn (refractive index as n is 4.7, extinction coefficient as k is 1.6@1000 nm) was vacuum deposited with a thickness of 20 nm to form a conductive protection layer. Deposition conditions were as follows. That is, a vacuum pressure was set at 5×10⁻⁵ Pa and a film deposition rate was set at 1 Å/sec.

Next, by a magnetron sputtering method, an ITO thin film (100 nm thick) was deposited to form a cathode. In the formation of the ITO thin film, a gas mixture of Ar and O₂ (volume ratio Ar: O₂=200: 1) was used as a sputtering gas, a pressure was set at 5.5×10⁻² Pa, a DC output was set at 150 W and a film deposition rate was set at 4 Å/sec.

Furthermore, on a transparent glass substrate, under conditions same as the above, on a Sn thin film, ITO was separately formed, and this was measured, under the conditions below, of the resistivity and the transmittance in the visible region of 380 to 780 nm. As a result, a surface resistance value of the ITO thin film containing a Sn thin film was 18 Ω/□. The average transmittance in the visible region was substantially 60%.

(Measurement of Surface Resistance)

The surface resistance value (Ω/□) was measured according to a four-probe method with Loresta-GP manufactured by Mitsubishi Chemicals Inc.

(Measurement of Resistivity)

The measured surface resistance value (Ω/□) was multiplied by a film thickness (cm) and thereby the resistivity value (Ω·cm) was calculated. As a film thickness, a film section was measured with Nanopics 1000 manufactured by Seiko Instruments Inc.

(Measurement of Light Transmittance)

The light transmittance was measured at room temperature in air by use of a UV-visible spectrophotometer (UV-2200A manufactured by Shinadzu Corporation).

Thereafter, in a globe box in a state of low oxygen (oxygen concentration is 1 ppm or less) and low humidity (water vapor concentration is 1 ppm or less), sealing was performed with non-alkali glass.

Thereby, an organic EL element that has an anode patterned in lines with a width of 2 mm; an electron injecting layer, a conductive protection layer and a cathode that are formed in lines with a width of 2 mm so as to be orthogonal to the anode; and four light-emitting areas (area of 4 mm²) was prepared.

A current density when a voltage of 6 V was applied between an anode and a cathode of the organic EL element was 200 mA/cm², and brightness of the light-emitting area measured from a top (cathode) side was 12000 cd/n².

From the results of the current density and brightness characteristics, it was confirmed that owing to the presence of the conductive protection layer made of a Sn thin film, oxidation of the light-emitting layer and the electron injecting layer due to oxygen introduction during the formation of the cathode and damage in the sputtering were inhibited from occurring.

### Example 2

Except that as a conductive protection layer, instead of the Sn thin film, an In (refractive index as n is 1.019, extinction coefficient as k is 2.08@500 nm) thin film (20 nm thick) was deposited under the same conditions, similarly to example 1, an organic EL element was prepared.

Similarly to example 1, the surface resistance value of an ITO film including the In thin film was measured and found to be 18 Ω/□. Furthermore, similarly to example 1, the light transmittance in the visible region of 380 to 780 nm was measured and found that average transmittance over the visible region was substantially 70%.

A current density when a voltage of 6 V was applied between an anode and a cathode of the organic EL element was 190 mA/cm², and brightness of a light-emitting area measured from a top (cathode) side was 12000 cd/m². From the results of the current density and brightness characteristics, it was confirmed that owing to the presence of the conductive protection layer made of the In thin film, oxidation of the light-emitting layer and the electron injecting layer due to oxygen introduction during the formation of the cathode and damage during the sputtering were inhibited from occurring.

### Example 3

Except that as a conductive protection layer, in place of the Sn thin film, azn (refractive index as nis 0.773, extinction coefficient as k is 3.912@545 nm) thin film (20 nm thick) was formed by a vacuum deposition method (vacuum pressure: 5×10⁻⁵ Pa, and film deposition rate: 1.0 Å/sec), similarly to example 1, an organic EL element was prepared.

Similarly to example 1, the surface resistance value of the ITO film including the Zn thin film was measured and found to be 19 Ω/□. Furthermore, similarly to example 1, average transmittance over the visible region of the ITO including the Zn thin film was measured and found to be substantially 70%.

A current density when a voltage of 6 V was applied between an anode and a cathode of the organic EL element was 190 mA/cm², and brightness of a light-emitting area measured from a top (cathode) side was 12000 cd/m². From the results of the current density and brightness characteristics, it was confirmed that owing to the presence of the conductive protection layer made of the Zn thin film, oxidation of the light-emitting layer and the electron injecting layer due to oxygen introduction during the formation of the cathode and damage during the sputtering were inhibited from occurring.

### Example 4

Except that as a conductive protection layer, in place of the Sn thin film, a Pb (refractive index as nis 1.68, extinction coefficient as k is 3.67700 nm) thin film (20 nm thick) was formed, similarly to example 1, an organic EL element was prepared.

Similarly to example 1, the surface resistance value of an ITO film including the Pb thin film was measured and found to be 15 Ω/□. Furthermore, similarly to example 1, average visible transmittance in the visible region of 380 to 780 nm of the ITO including the Pb thin film was measured and found to be substantially 60%.

A current density when a voltage of 6 V was applied between an anode and a cathode of the organic EL element was 200 mA/cm², and brightness of a light-emitting area measured from a top (cathode) side was 11000 cd/m². From the results of the current density and brightness characteristics, it was confirmed that owing to the presence of the conductive protection layer made of the Pb thin film, oxidation of the light-emitting layer and the electron injecting layer due to oxygen introduction during the formation of the cathode and damage during the sputtering were inhibited from occurring.

### Example 5

Except that as a conductive protection layer, Sn (20 nm thick) was formed, and as the second electrode (cathode), instead of the ITO film, a thin film of indium zinc oxide (IZO) that is an inorganic oxide was formed, similarly to example 1, an organic EL element was prepared. As a sputtering gas, only Ar was used, a pressure was set at 5.5×10⁻² Pa, a DC output was set at 150 W, and a film deposition rate was set at 4 Å/sec.

Similarly to example 1, the surface resistance value of an ITO film including the Sn thin film was measured and found to be 19 Ω/□. Furthermore, similarly to example 1, average transmittance over a visible region of the IZO thin film including the Sn thin film was measured and found to be substantially 70%.

A current density when a voltage of 6 V was applied between an anode and a cathode of the organic EL element was 210 mA/cm², and brightness of a light-emitting area measured from a top (cathode) side was 12000 cd/m². From the results of the current density and brightness characteristics, it was confirmed that owing to the presence of the conductive protection layer made of the Sn thin film, oxidation of the electron injecting layer due to oxygen introduction during the formation of the cathode and damage during the sputtering were inhibited from occurring.

### Comparative Example 1

Except that a conductive protection layer was not formed, similarly to example 1, an organic EL element was prepared.

A current density when a voltage of 6 V was applied between an anode and a cathode of the organic EL element was 30 mA/cm², and brightness of a light-emitting area measured from a top (cathode) side was 2000 cd/m². From the results of the current density and brightness characteristics, it was confirmed that in an element in which a conductive protection layer was not formed, owing to oxidation of the electron injecting layer due to oxygen during the formation of the cathode, the emission characteristics were deteriorated.

### Example 6

Firstly, similarly to example 1, an anode was formed on a transparent glass substrate, followed by exposing the transparent glass substrate with the anode under oxygen plasma, further followed by forming a hole transporting layer (50 nm thick) made of bis(N-naphtyl)-N-phenylbenzidine (α-NPD) expressed by the following structural formula (3) by vacuum heating vapor deposition method on the transparent glass substrate so as to cover the anode. The deposition conditions of the hole transporting layer were set such that vacuum pressure was 5×10⁻⁵ Pa, the film deposition rate was 3 Å/sec, and the heating temperature was 350° C.

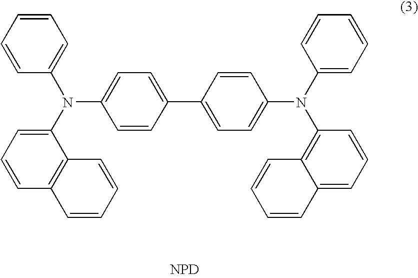

Next, according to the vacuum deposition method, on the hole transporting layer, tris(8-quinolirate)aluminum complex (Alq3) expressed by the following structural formula (4) was deposited and thereby a light-emitting layer (60 nm thick) was formed. The deposition conditions of the light-emitting layer were set such that vacuum pressure was 5×10⁻⁵ Pa and the film deposition rate was 3 Å/sec.

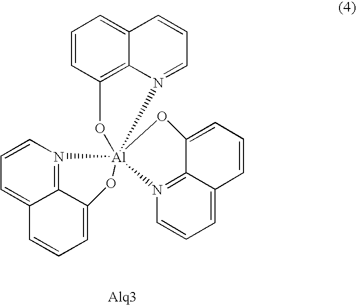

Furthermore, by the vacuum deposition method, on the light-emitting layer, a co-deposition layer of bathocuproin (BCP) expressed by the following structural formula (5) and Li was formed, and thereby an electron injecting layer (20 nm thick) was formed. The deposition conditions were set such that the vacuum pressure was 5×10⁻⁵ Pa and the film deposition rate of the respective materials was 3 Å/sec.

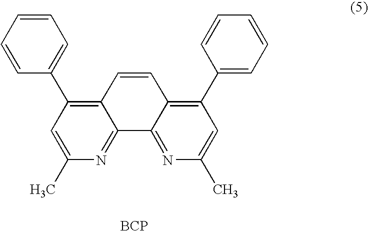

Subsequently, similarly to example 1, a conductive protection layer Sn and a cathode ITO were formed, followed by finally sealing with sealing glass.

A current density when a voltage of 6 V was applied between an anode and a cathode of the organic EL element was 40 mA/cm², and brightness of a light-emitting area measured from a top (cathode) side was 3000 cd/m². From the results of the current density and brightness characteristics, it was confirmed that owing to the presence of the conductive protection layer made of Sn thin film, oxidation of the electron injecting layer due to oxygen during the formation of the cathode and damage during the sputtering were inhibited from occurring.

### Comparative Example 2

Except that a conductive protection layer was not formed, similarly to example 6, an organic EL element was prepared.

A current density when a voltage of 6 V was applied between an anode and a cathode of the organic EL element was 2.8 MA/cm², and brightness of a light-emitting area measured from a top (cathode) side was 160 cd/m². From the results of the current density and brightness characteristics, it was confirmed that in the element in which a conductive protection layer was not formed, oxidation of the electron injecting layer due to oxygen during the formation of the cathode and damage during the sputtering were not inhibited from occurring.

1. An organic electroluminescent element, comprising at least a base material and, sequentially formed from the base material side, an anode, an organic electroluminescent layer, a conductive protection layer having the optical transparency and a cathode having the optical transparency, wherein the conductive protection layer is made of a metal or a metal and a metal oxide thereof.

2. The organic electroluminescent element according to claim 1, wherein a metal used in the conductive protection layer, with extinction coefficient of the metal as k, a film thickness as d and a wavelength as λ, is in the range of 0≦k×d<0.11λ.

3. The organic electroluminescent element according to claim 1, wherein the metal oxide contained in the conductive protection layer has a band gap of 2.9 eV or more.

4. The organic electroluminescent element according to claim 1, wherein the conductive protection layer is constituted of at least one kind of metals selected from a group consisting of zinc, tin, lead, indium, gallium, magnesium and aluminum, or a combination of at least one kind of the metals and at least one kind of the metal oxides thereof.

5. The organic electroluminescent element according to claim 1, wherein the cathode is made of a conductive oxide and has a thickness in the range of 10 to 500 nm and the light transmittance of 50% or more in a visible region of 380 to 780 nm.

6. The organic electroluminescent element according to claim 1, wherein the sheet resistance of the cathode containing the conductive protection layer is 20 Ω/□ or less.

7. The organic electroluminescent element according to claim 1, wherein the anode is made of any one of one kind or a combination of two or more kinds of metals of a metal group having a work function of 4.5 eV or more, or an alloy made of two or more kinds of metals among the metal group, or one kind or two or more kinds of a group of conductive inorganic oxides.

8. The organic electroluminescent element according to claim 7, wherein the anode has a structure in which a layer made of the metal or the alloy and a layer made of the conductive inorganicoxide are laminated in this order from the base material side and has the light reflectiveness.

9. The organic electroluminescent element according to claim 7, wherein the anode is made of the metal or the alloy and has the light reflectiveness.
